(19) United States
(12) Patent Application Publication
(10) Pub. No.: US 2025/0013794 A1
(43) Pub. Date: Jan. 9, 2025

(54) ARITHMETIC CIRCUIT AND ARITHMETIC PROGRAM

(71) Applicant: Murata Manufacturing Co., Ltd., Kyoto (JP)

(72) Inventors: Tomoshige FURUHI, Kyoto (JP); Takashi WATANABE, Kyoto (JP); Takashi HAGA, Kyoto (JP); Takehiko IIZUKA, Kyoto (JP); Nobuyuki NOZAWA, Kyoto (JP); Jun MAKINO, Kyoto (JP)

(21) Appl. No.: 18/891,291

(22) Filed: Sep. 20, 2024

Related U.S. Application Data
(63) Continuation of application No. PCT/JP2023/007744, filed on Mar. 2, 2023.

(30) Foreign Application Priority Data
Mar. 23, 2022 (JP) 2022-046927

(51) Int. Cl. G06F 30/10; G06F 17/16

(52) U.S. Cl. CPC G06F 30/10; G06F 17/16

(57) ABSTRACT

An arithmetic circuit according to the present disclosure performs a signal value acquisition step of acquiring X-axis bending values, Y-axis bending values, and twisting values at respective one or more first times before an impact time identified in a time identification step and at respective one or more second times after the impact time; and a first calculation step of calculating one or more parameters indicating a state of an object to be measured at the impact time by multiplying a plurality of the X-axis bending values, a plurality of the Y-axis bending values, and a plurality of the twisting values acquired in the signal value acquisition step by a matrix.

### CROSS REFERENCE TO RELATED APPLICATION

This is a continuation of International Application No. PCT/JP2023/007744 filed on Mar. 2, 2023 which claims priority from Japanese Patent Application No. 2022-046927 filed on Mar. 23, 2022. The contents of these applications are incorporated herein by reference in their entireties.

### BACKGROUND ART

### Technical Field

The present disclosure relates to an arithmetic circuit and an arithmetic program.

As an disclosure relating to an existing arithmetic circuit, for example, there is a device disclosed in Patent Document 1. This device includes a measuring device that can measure a head speed, and a carry of a hit ball. An example of the measuring device is a trajectory measuring instrument TrackMan manufactured by Interactive Sports Games A/S.
Patent Document 1: Japanese Unexamined Patent Application Publication No. 2016-123487

### BRIEF SUMMARY

In the device disclosed in Patent document 1, however, an expensive TrackMan is suitable.

Thus, the present disclosure aims to inexpensively provide an arithmetic device and an arithmetic program that can calculate one or more parameters indicating a state of an object to be measured at a time of impact between the object to be measured and a measuring object.

An arithmetic circuit according to an aspect of the present disclosure performs:
a signal acquisition step of acquiring an X-axis bending signal related to an amount of bending in an X-axis direction of a stick-like object to be measured extending in a Z-axis direction, a Y-axis bending signal related to an amount of bending in a Y-axis direction of the object to be measured, and a twisting signal related to an amount of twisting around a Z axis of the object to be measured;
a time identification step of identifying, in accordance with the X-axis bending signal, the Y-axis bending signal, and the twisting signal acquired in the signal acquisition step, an impact time when the object to be measured hit an object to be hit;
a signal value acquisition step of acquiring X-axis bending values, Y-axis bending values, and twisting values at respective one or more first times before the impact time identified in the time identification step and at respective one or more second times after the impact time, each X-axis bending value being a value related to a value indicated by the X-axis bending signal, each Y-axis bending value being a value related to a value indicated by the Y-axis bending signal, and each twisting value being a value related to a value indicated by the twisting signal; and
a first calculation step of calculating one or more parameters indicating a state of the object to be measured at the impact time by multiplying a plurality of the X-axis bending values, a plurality of the Y-axis bending values, and a plurality of the twisting values acquired in the signal value acquisition step by a matrix.

An arithmetic program according to an aspect of the present disclosure causes an arithmetic circuit to perform:
a signal acquisition step of acquiring an X-axis bending signal related to an amount of bending in an X-axis direction of a stick-like object to be measured extending in a Z-axis direction, a Y-axis bending signal related to an amount of bending in a Y-axis direction of the object to be measured, and a twisting signal related to an amount of twisting around a Z axis of the object to be measured;
a time identification step of identifying, in accordance with the X-axis bending signal, the Y-axis bending signal, and the twisting signal acquired in the signal acquisition step, an impact time when the object to be measured hit an object to be hit;
a signal value acquisition step of acquiring X-axis bending values, Y-axis bending values, and twisting values at respective one or more first times before the impact time identified in the time identification step and at respective one or more second times after the impact time, each X-axis bending value being a value related to a value indicated by the X-axis bending signal, each Y-axis bending value being a value related to a value indicated by the Y-axis bending signal, and each twisting value being a value related to a value indicated by the twisting signal; and
a first calculation step of calculating one or more parameters indicating a state of the object to be measured at the impact time by multiplying a plurality of the X-axis bending values, a plurality of the Y-axis bending values, and a plurality of the twisting values acquired in the signal value acquisition step by a matrix.

An arithmetic circuit according to an aspect of the present disclosure performs:
a signal acquisition step of acquiring an X-axis bending signal related to an amount of bending in an X-axis direction of a stick-like object to be measured extending in a Z-axis direction, a Y-axis bending signal related to an amount of bending in a Y-axis direction of the object to be measured, and a twisting signal related to an amount of twisting around a Z axis of the object to be measured;
an initial value acquisition step of acquiring a velocity of a center of gravity of an object to be hit and an angular velocity of the object to be hit produced by impact between the object to be measured and the object to be hit; and
a model generation step of generating a machine learning model by using, as training data, the X-axis bending signal, the Y-axis bending signal, and the twisting signal acquired in the signal acquisition step, and the velocity of the center of gravity of the object to be hit and the angular velocity of the object to be hit acquired in the initial value acquisition step, the machine learning model being configured to output, in accordance with the X-axis bending signal, the Y-axis bending signal, and the twisting signal, the velocity of the center of gravity of the object to be hit and the angular velocity of the object to be hit.

An arithmetic program according to an aspect of the present disclosure causes an arithmetic circuit to perform:
a signal acquisition step of acquiring an X-axis bending signal related to an amount of bending in an X-axis direction of a stick-like object to be measured extending in a Z-axis direction, a Y-axis bending signal related to an amount of bending in a Y-axis direction of the object to be measured, and a twisting signal related to an amount of twisting around a Z axis of the object to be measured;
an initial value acquisition step of acquiring a velocity of a center of gravity of an object to be hit and an angular velocity of the object to be hit produced by impact between the object to be measured and the object to be hit; and
a model generation step of generating a machine learning model by using, as training data, the X-axis bending signal, the Y-axis bending signal, and the twisting signal acquired in the signal acquisition step, and the velocity of the center of gravity of the object to be hit and the angular velocity of the object to be hit acquired in the initial value acquisition step, the machine learning model being configured to output, in accordance with the X-axis bending signal, the Y-axis bending signal, and the twisting signal, the velocity of the center of gravity of the object to be hit and the angular velocity of the object to be hit.

An arithmetic circuit according to an aspect of the present disclosure performs:
a signal acquisition step of acquiring an X-axis bending signal related to an amount of bending in an X-axis direction of a stick-like object to be measured extending in a Z-axis direction, a Y-axis bending signal related to an amount of bending in a Y-axis direction of the object to be measured, and a twisting signal related to an amount of twisting around a Z axis of the object to be measured; and
a machine learning calculation step of calculating, by using a machine learning model, in accordance with the X-axis bending signal, the Y-axis bending signal, and the twisting signal acquired in the signal acquisition step, a velocity of a center of gravity of an object to be hit and an angular velocity of the object to be hit produced by impact between the object to be measured and the object to be hit.

An arithmetic program according to an aspect of the present disclosure causes an arithmetic circuit to perform:
a signal acquisition step of acquiring an X-axis bending signal related to an amount of bending in an X-axis direction of a stick-like object to be measured extending in a Z-axis direction, a Y-axis bending signal related to an amount of bending in a Y-axis direction of the object to be measured, and a twisting signal related to an amount of twisting around a Z axis of the object to be measured; and
a machine learning calculation step of calculating, by using a machine learning model, in accordance with the X-axis bending signal, the Y-axis bending signal, and the twisting signal acquired in the signal acquisition step, a velocity of a center of gravity of an object to be hit and an angular velocity of the object to be hit produced by impact between the object to be measured and the object to be hit.

The present disclosure can inexpensively provide the arithmetic device and the arithmetic program that can calculate one or more parameters indicating a state of the object to be measured at a time of impact between the object to be measured and the measuring object.

### BRIEF DESCRIPTION OF THE DRAWINGS

FIG. 1 illustrates a golf club 200 where a sensor unit 100 is installed.

FIG. 2 includes a top view and a cross-sectional view of a sensor 12a.

FIG. 3 includes a top view and a cross-sectional view of a sensor 12c.

FIG. 4 is a block diagram of an arithmetic device 1.

FIG. 5 is a flowchart illustrating a sequence of operations performed by an arithmetic circuit 10.

FIG. 6 is a waveform diagram illustrating an X-axis bending signal Sig1, a Y-axis bending signal Sig2, and a twisting signal Sig3.

FIG. 7 is a waveform diagram illustrating an X-axis bending amount aₓ(i), a Y-axis bending amount a_{y}(i), and a twisting amount aₜ(i).

FIG. 8 illustrates a head of the golf club 200 and a golf ball 210.

FIG. 9 is a table illustrating judgement criteria.

FIG. 10 is a table illustrating experimental results.

FIG. 11 is a flowchart illustrating a sequence of operations performed by an arithmetic circuit 10a.

FIG. 12 is a flowchart illustrating a sequence of operations performed by the arithmetic circuit 10a.

### DETAILED DESCRIPTION

### Embodiment

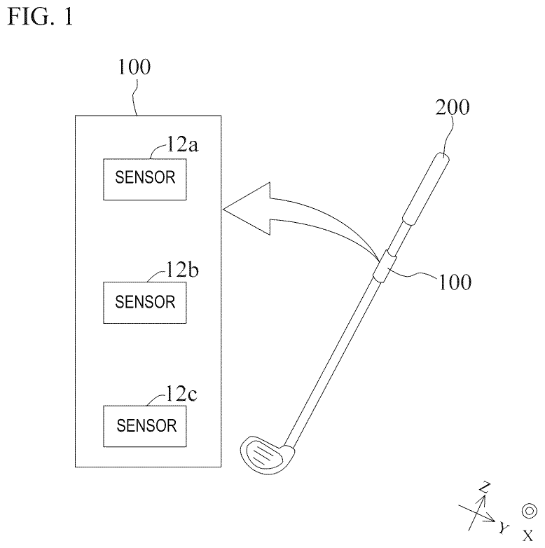

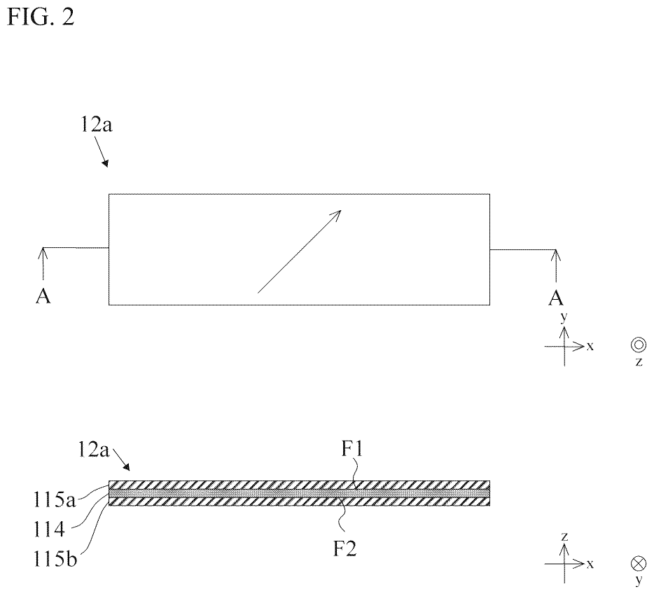

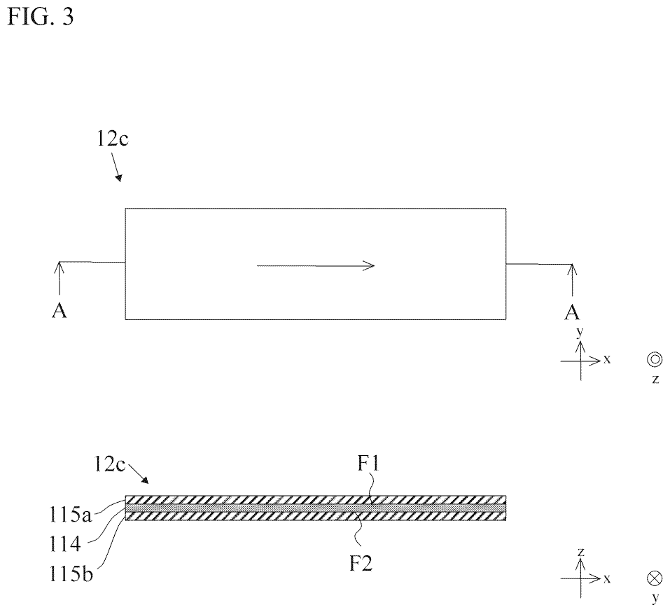

An arithmetic circuit 10 according to an embodiment of the present disclosure will be described below with reference to drawings. FIG. 1 illustrates a golf club 200 where a sensor unit 100 is installed. FIG. 2 includes a top view and a cross-sectional view of a sensor 12a. FIG. 3 includes a top view and a cross-sectional view of a sensor 12c.

Furthermore, in the present description, directions are defined as follows. As illustrated in FIG. 1, the golf club 200 is a stick-like member. A direction in which the golf club 200 extends is defined as a Z-axis direction. A positive direction of a Z axis is a direction from a head of the golf club 200 toward a grip. A direction that a face of the head of the golf club 200 faces is defined as a positive direction of an X axis. A Y-axis direction is orthogonal to an X-axis direction and the Z-axis direction.

The sensor unit 100 is installed at the golf club 200 as illustrated in FIG. 1. The sensor unit 100 detects a deformation of the golf club 200 at the time of swing.

The sensor unit 100 includes sensors 12a to 12c as illustrated in FIG. 1. The sensors 12a to 12c detect a deformation of the golf club 200. Specifically, the sensor 12a detects a bending in the X-axis direction of the golf club 200. The sensor 12b detects a bending in the Y-axis direction of the golf club 200. The sensor 12c detects twisting around the Z axis of the golf club 200. Structures of the sensors 12a and 12b are the same, and thus the sensor 12a will be described as an example below.

The sensor 12a includes, as illustrated in FIG. 2, a piezoelectric film 114, a first electrode 115a, and a second electrode 115b. The piezoelectric film 114 is sheet-shaped. The piezoelectric film 114 is rectangular. Hereinafter, a direction in which a long side of the piezoelectric film 114 extends is defined as an x-axis direction. A direction in which a short side of the piezoelectric film 114 extends is defined as a y-axis direction. A direction that is orthogonal to the x-axis direction and the y-axis direction is defined as a z-axis direction.

The piezoelectric film 114 has a first main surface F1 and a second main surface F2. A length in the x-axis direction of the piezoelectric film 114 is longer than a length in the y-axis direction of the piezoelectric film 114. The piezoelectric film 114 generates an electric charge corresponding to the amount of deformation of the piezoelectric film 114. In the present embodiment, the piezoelectric film 114 is a PLA film. The piezoelectric film 114 will be described in more detail below.

The piezoelectric film 114 has characteristics in which the polarity of an electric charge generated when the piezoelectric film 114 is deformed so as to be extended in the x-axis direction is opposite to the polarity of an electric charge generated when the piezoelectric film 114 is deformed so as to be extended in the y-axis direction. Specifically, the piezoelectric film 114 is a film made of a chiral polymer. The chiral polymer is, for example, polylactic acid (PLA), particularly poly-L-lactic acid (PLLA). PLLA composed of a chiral polymer has a main chain with a helical structure. PLLA has piezoelectricity in which molecules are oriented when the PLLA is uniaxially stretched. The piezoelectric film 114 has a piezoelectric constant of d14. A uniaxial stretching direction (orientation direction) of the piezoelectric film 114 makes an angle of 45 degrees with respect to each of the x-axis direction and the y-axis direction. The angle of 45 degrees includes, for example, angles of 45 degrees±about 10 degrees. Thus, the piezoelectric film 114 generates an electric charge when deformed so as to be extended in the x-axis direction or when deformed so as to be compressed in the x-axis direction. Hence, an output of the sensor 12a is an electric charge. The piezoelectric film 114 generates, for example, a positive electric charge when deformed so as to be extended in the x-axis direction. The piezoelectric film 114 generates, for example, a negative electric charge when deformed so as to be compressed in the x-axis direction. The magnitude of an electric charge depends on the amount of deformation in the x-axis direction of the piezoelectric film 114 due to extension or compression.

The first electrode 115a is a signal electrode. The first electrode 115a is provided on the first main surface F1. The first electrode 115a is, for example, an organic electrode made of, for example, indium tin oxide (ITO) or zinc oxide (ZnO), a metal film formed by vapor deposition or plating, or a printed electrode film using silver paste.

The second electrode 115b is a ground electrode. The second electrode 115b is connected to a ground potential. The second electrode 115b is provided on the second main surface F2. Thus, the piezoelectric film 114 is located between the first electrode 115a and the second electrode 115b. The second electrode 115b covers the second main surface F2. The second electrode 115b is, for example, an organic electrode made of, for example, indium tin oxide (ITO) or zinc oxide (ZnO), a metal film formed by vapor deposition or plating, or a printed electrode film using silver paste.

The sensor 12c differs from the sensor 12a in the uniaxial stretching direction of the piezoelectric film 114. More specifically, as illustrated in FIG. 3, the uniaxial stretching direction (orientation direction) of the piezoelectric film 114 of the sensor 12c is parallel to the x-axis direction. The other structure of the sensor 12c is the same as that of the sensor 12a, and a description thereof is omitted.

The sensor 12a outputs an X-axis bending signal Sig1 related to the amount of bending in the X-axis direction of the golf club 200 (object to be measured). In the present embodiment, the X-axis bending signal Sig1 includes the amount of bending in the X-axis direction of the golf club 200. More specifically, the sensor 12a is fixed to the golf club 200 with an adhesive layer, which is not illustrated, interposed between the sensor 12a and the golf club 200. Specifically, the adhesive layer fixes the golf club 200 and the first electrode 115a to each other. At this time, the sensor 12a is fixed to a surface facing the positive direction of the X axis of a shaft of the golf club 200 so that the x-axis direction coincides with a Z axis direction. Thus, when the shaft of the golf club 200 bends in the positive direction of the X axis, the amount of shrinkage in the Z-axis direction of the surface facing the positive direction of the X axis of the shaft of the golf club 200 increases. Hence, the amount of shrinkage in the x-axis direction of the piezoelectric film 114 increases. As a result, a positive electric charge is generated on the first main surface F1 of the piezoelectric film 114. A negative electric charge is generated on the second main surface F2 of the piezoelectric film 114. When the shaft of the golf club 200 bends in a negative direction of the X axis, the amount of extension in the Z-axis direction of the surface facing the positive direction of the X axis of the shaft of the golf club 200 increases. Hence, the amount of extension in the x-axis direction of the piezoelectric film 114 increases. As a result, a negative electric charge is generated on the first main surface F1 of the piezoelectric film 114. A positive electric charge is generated on the second main surface F2 of the piezoelectric film 114.

The sensor 12b outputs a Y-axis bending signal Sig2 related to the amount of bending in the Y-axis direction of the golf club 200 (object to be measured). In the present embodiment, the Y-axis bending signal Sig2 includes the amount of bending in the Y-axis direction of the golf club 200. More specifically, the sensor 12b is fixed to the golf club 200 with an adhesive layer, which is not illustrated, interposed between the sensor 12b and the golf club 200. Specifically, the adhesive layer fixes the golf club 200 and the first electrode 115a to each other. At this time, the sensor 12b is fixed to a surface facing a positive direction of a Y axis of the shaft of the golf club 200 so that the x-axis direction coincides with the Z-axis direction. Thus, when the shaft of the golf club 200 bends in the positive direction of the Y axis, the amount of shrinkage in a vertical direction of the surface facing the positive direction of the Y axis of the shaft of the golf club 200 increases. Hence, the amount of shrinkage in the x-axis direction of the piezoelectric film 114 increases. As a result, a positive electric charge is generated on the first main surface F1 of the piezoelectric film 114. A negative electric charge is generated on the second main surface F2 of the piezoelectric film 114. When the shaft of the golf club 200 bends in a negative direction of the Y axis, the amount of extension in the vertical direction of the surface facing the positive direction of the Y axis of the shaft of the golf club 200 increases. Hence, the amount of extension in the x-axis direction of the piezoelectric film 114 increases. As a result, a negative electric charge is generated on the first main surface F1 of the piezoelectric film 114. A negative electric charge is generated on the second main surface F2 of the piezoelectric film 114.

The sensor 12c outputs a twisting signal Sig3 related to the amount of twisting around the Z axis of the golf club 200 (object to be measured). In the present embodiment, the twisting signal Sig3 includes the amount of twisting around the Z axis of the golf club 200. More specifically, the sensor 12c is fixed to the golf club 200 with an adhesive layer, which is not illustrated, interposed between the sensor 12c and the golf club 200. Specifically, the adhesive layer fixes the golf club 200 and the first electrode 115a to each other. At this time, the sensor 12c is fixed to the shaft of the golf club 200 so that the x-axis direction coincides with the Z-axis direction. Thus, when the shaft of the golf club 200 twists in a first circumferential direction around the Z axis, the amount of extension in a direction making an angle of 45 degrees with respect to each of the x-axis direction and the y-axis direction of the piezoelectric film 114 increases. As a result, a negative electric charge is generated on the first main surface F1 of the piezoelectric film 114. A positive electric charge is generated on the second main surface F2 of the piezoelectric film 114. When the shaft of the golf club 200 twists in a second circumferential direction around the Z axis, the amount of shrinkage in the direction making an angle of 45 degrees with respect to each of the x-axis direction and the y-axis direction of the piezoelectric film 114 increases. As a result, a positive electric charge is generated on the first main surface F1 of the piezoelectric film 114. A negative electric charge is generated on the second main surface F2 of the piezoelectric film 114.

Furthermore, the sensor unit 100 includes, for example, an A/D converter that converts the X-axis bending signal Sig1, the Y-axis bending signal Sig2, and the twisting signal Sig3 into digital signals, and a transmission device that transmits the X-axis bending signal Sig1, the Y-axis bending signal Sig2, and the twisting signal Sig3 to an arithmetic device 1 to be described. Note that the A/D converter and the transmission device have respective typical configurations, and an illustration and a description thereof are omitted.

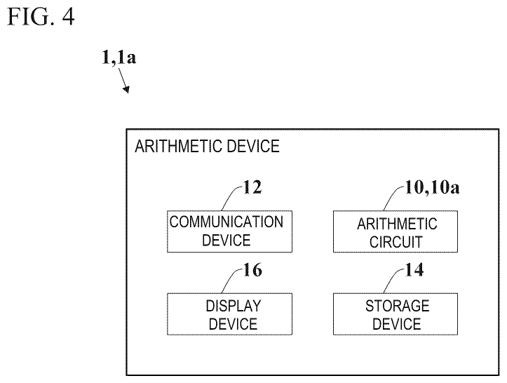

Next, the arithmetic device 1 will be described with reference to a drawing. FIG. 4 is a block diagram of the arithmetic device 1.

The arithmetic device 1 is, for example, a personal computer, a server, or a smartphone. The arithmetic device 1 includes the arithmetic circuit 10, a communication device 12, a storage device 14, and a display device 16. The arithmetic circuit 10 is a Central Processing Unit (CPU). The communication device 12 is a device that communicates by wire or wirelessly with the sensor unit 100. The storage device 14 is, for example, a memory, or a hard disk. The display device 16 is, for example, an organic EL display, or a liquid crystal display.

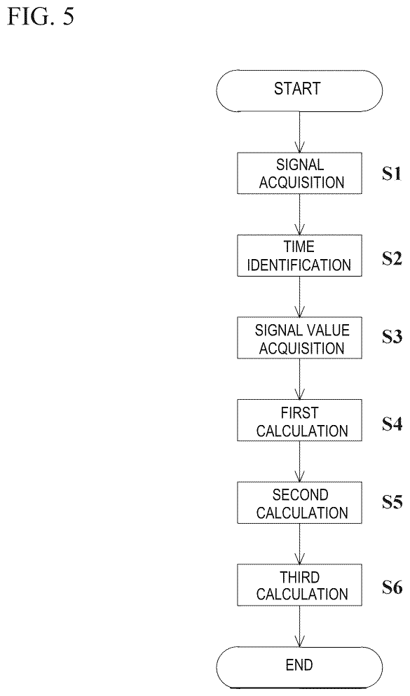

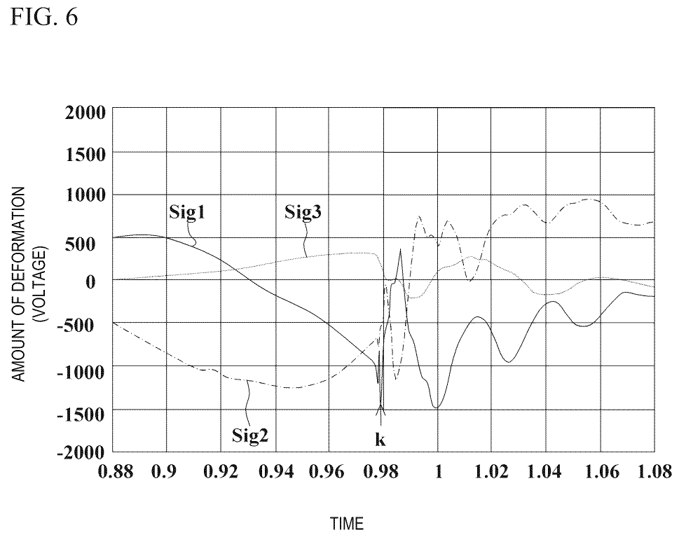

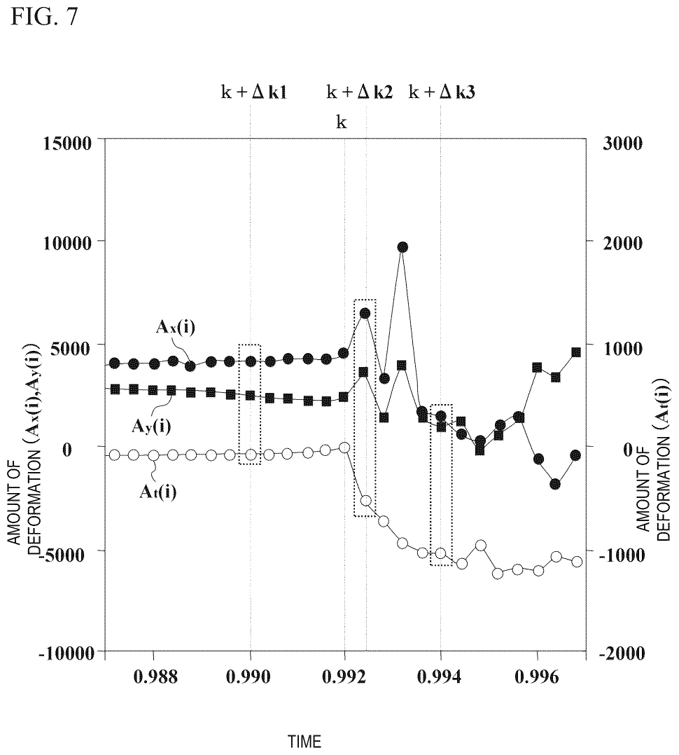

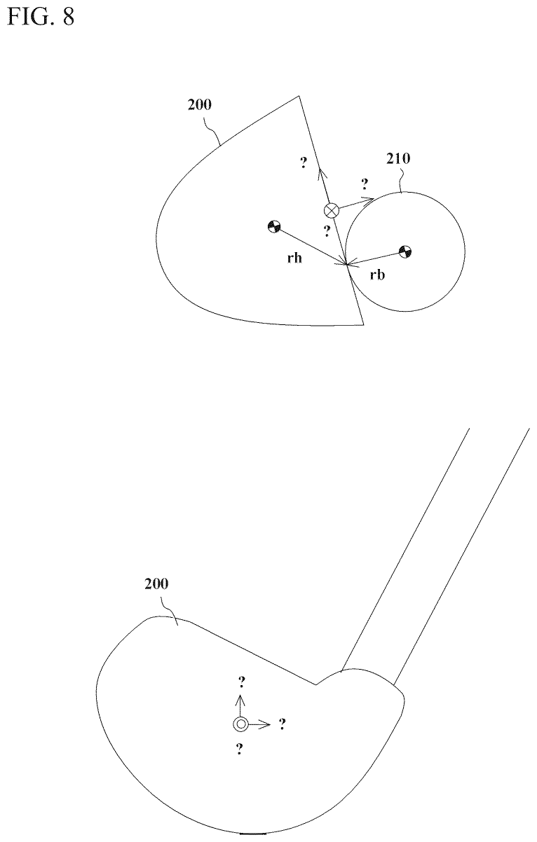

The operation of the arithmetic device 1 will be described below with reference to a drawing. FIG. 5 is a flowchart illustrating a sequence of operations performed by the arithmetic circuit 10. The operations of the flowchart are performed by the arithmetic circuit 10 reading a program stored in the storage device 14. FIG. 6 is a waveform diagram illustrating an X-axis bending signal Sig1, a Y-axis bending signal Sig2, and a twisting signal Sig3. FIG. 7 is a waveform diagram illustrating an X-axis bending amount aₓ(i), a Y-axis bending amount a_{y}(i), and a twisting amount aₜ(i). FIG. 8 illustrates the head of the golf club 200 and a golf ball 210.

A user hits the golf ball 210 with the golf club 200. Subsequently, the sensor unit 100 transmits an X-axis bending signal Sig1, a Y-axis bending signal Sig2, and a twisting signal Sig3 to the arithmetic device 1 by using a transmission device, which is not illustrated. In response to this, the communication device 12 receives the X-axis bending signal Sig1, the Y-axis bending signal Sig2, and the twisting signal Sig3 transmitted from the sensor unit 100. The communication device 12 outputs the X-axis bending signal Sig1, the Y-axis bending signal Sig2, and the twisting signal Sig3 to the arithmetic circuit 10. Thus, the arithmetic circuit 10 acquires the X-axis bending signal Sig1, the Y-axis bending signal Sig2, and the twisting signal Sig3 that are illustrated in FIG. 6 (Step S1, signal acquisition step).

Next, the arithmetic circuit 10 identifies, in accordance with the X-axis bending signal Sig1, the Y-axis bending signal Sig2, and the twisting signal Sig3 acquired in Step S1 (signal acquisition step), an impact time k when the golf club 200 (object to be measured) hit the golf ball 210 (object to be hit) (Step S2, time identification step). Specifically, the arithmetic circuit 10 multiplies each of the X-axis bending signal Sig1, the Y-axis bending signal Sig2, and the twisting signal Sig3 by a constant. Thus, the arithmetic circuit 10 obtains an X-axis bending amount aₓ(i), a Y-axis bending amount a_{y}(i), and a twisting amount aₜ(i) illustrated in FIG. 7. The letter i represents a time. Then, the arithmetic circuit 10 identifies, as an impact time k, a time when time derivatives of the X-axis bending amount aₓ(i), the Y-axis bending amount a_{y}(i), and the twisting amount aₜ(i) exceed respective threshold values. Incidentally, the arithmetic circuit 10 may identify, as an impact time k, a time when a time derivative of the X-axis bending amount aₓ(i) exceeds a threshold value, may identify, as an impact time k, a time when a time derivative of the Y-axis bending amount a_{y}(i) exceeds a threshold value, or may identify, as an impact time k, a time when a time derivative of the twisting amount aₜ(i) exceeds a threshold value.

Next, the arithmetic circuit 10 acquires, at a first time k+Δk1 before the impact time k identified in Step S2 (time identification step) and at second times k+Δk2 and k+Δk3 after the impact time k, X-axis bending amounts aₓ(k+Δk1), aₓ(k+Δk2), and aₓ(k+Δk3) (X-axis bending values), Y-axis bending amounts a_{y}(k+Δk1), a_{y}(k+Δk2), and a_{y}(k+Δk3) (Y-axis bending values), and twisting values aₜ(k+Δk1), aₜ(k+Δk2), and aₜ(k+Δk3) (twisting values) (S3, signal value acquisition step). Here, the X-axis bending amounts aₓ(k+Δk1), aₓ(k+Δk2), and aₓ(k+Δk3) (X-axis bending values) are values related to a value indicated by the X-axis bending signal Sig1. The Y-axis bending amounts a_{y}(k+Δk1), a_{y}(k+Δk2), and a_{y}(k+Δk3) (Y-axis bending values) are values related to a value indicated by the Y-axis bending signal Sig2. The twisting values aₜ(k+Δk1), aₜ(k+Δk2), and aₜ(k+Δk3) (twisting values) are values related to a value indicated by the twisting signal Sig3.

Next, parameters B1 to B8 indicating a state of the golf club 200 (object to be measured) at the impact time k are calculated by multiplying the X-axis bending amounts aₓ(k+Δk1), aₓ(k+Δk2), and aₓ(k+Δk3) (X-axis bending values), the Y-axis bending amounts a_{y}(k+Δk1), a_{y}(k+Δk2), and a_{y}(k+Δk3) (Y-axis bending values), and the twisting values aₜ(k+Δk1), aₜ(k+Δk2), and aₜ(k+Δk3) (twisting values) acquired in Step S3 (signal value acquisition step) by a matrix R (Step S4, first calculation step). Specifically, the arithmetic circuit 10 calculates the following a1 to a9.

$$\begin{matrix}a 1 = {a}_{x} ( k + Δ k 1 ) - {a}_{x} ( k ) \\ a 2 = {a}_{y} ( k + Δ k 1 ) - {a}_{y} ( k ) \\ a 3 = {a}_{t} ( k + Δ k 1 ) - {a}_{t} ( k ) \\ a 4 = {a}_{x} ( k + Δ k 2 ) - {a}_{x} ( k ) \\ a 5 = {a}_{y} ( k + Δ k 2 ) - {a}_{y} ( k ) \\ a 6 = {a}_{t} ( k + Δ k 2 ) - {a}_{t} ( k ) \\ a 7 = {a}_{x} ( k + Δ k 3 ) - {a}_{x} ( k ) \\ a 8 = {a}_{y} ( k + Δ k 3 ) - {a}_{y} ( k ) \\ a 9 = {a}_{t} ( k + Δ k 3 ) - {a}_{t} ( k )\end{matrix}$$

Furthermore, the arithmetic circuit 10 performs the operation of the following Equation 1. Thus, the arithmetic circuit 10 calculates the parameters B1 to B8.

$$\begin{matrix}[ Math . 1 ] & \\ \begin{matrix}( \begin{matrix}B 1 \\ ⋮ \\ B 8\end{matrix} ) = ( \begin{matrix}r 11 & … & r 19 \\ ⋮ & ⋱ & ⋮ \\ r 81 & … & r 89\end{matrix} ) ( \begin{matrix}a 1 \\ ⋮ \\ a 9\end{matrix} ) + ( \begin{matrix}C 1 \\ ⋮ \\ C 8\end{matrix} ) \\ B = R \cdot A + C\end{matrix} & ( Equation 1 )\end{matrix}$$

B1: location in an η-axis direction (mm) of a point of impact between the head of the golf club 200 and the golf ball 210

B2: location in a ζ-axis direction (mm) of a point of impact between the head of the golf club 200 and the golf ball 210

B3: horizontal azimuth angle (deg) of the head of the golf club 200

B4: head elevation angle (deg)

B5: head speed (m/s)

B6: head speed elevation angle (deg)

B7: head speed azimuth angle (deg)

B8: head vertical rotation speed (rps)

Here, the matrix R and a constant C are calculated, for example, by experiment. Specifically, inventors of the present application performed multiple actions of hitting the golf ball 210 with the golf club 200. Subsequently, each inventor of the present application acquired, for each action, X-axis bending amounts aₓ(k+Δk1), aₓ(k+Δk2), and aₓ(k+Δk3) (X-axis bending values), Y-axis bending amounts a_{y}(k+Δk1), a_{y}(k+Δk2), and a_{y}(k+Δk3) (Y-axis bending values), and twisting values aₜ(k+Δk1), aₜ(k+Δk2), and aₜ(k+Δk3) (twisting values). Furthermore, the inventor of the present application performed measurement and calculation of the parameters B1 to B8 for each action. Then, the inventor of the present application calculated, by using a calculation method, such as the method of least squares, the matrix R and the constant C so that the calculated parameters B1 to B8 get close to the measured parameter B1 to B8.

Next, the arithmetic circuit 10 calculates, in accordance with the parameters B1 to B8 acquired in Step S4 (first calculation step), a velocity of the center of gravity V_{gc} of the golf ball 210 (object to be hit) and an angular velocity ω of the golf ball 210 (object to be hit) produced by impact between the golf club 200 (object to be measured) and the golf ball 210 (object to be hit) (Step S5, second calculation step). A calculation method for the velocity of the center of gravity V_{gc} and the angular velocity ω will be described below.

$$\begin{matrix}[ Math . 2 ] & \\ {V}_{h}^{′} = {V}_{gc}^{′} + {Ω}^{′} \times {r}_{h} & ( Equation 2 )\end{matrix}$$

$$\begin{matrix}[ Math . 3 ] & \\ {V}_{h} = ( {V}_{gc}^{′} - \frac{Δ P}{M} ) + [ {Ω}^{′} - {I}_{h}^{- 1} ( {r}_{h} \times Δ P ) ] \times {r}_{h} & ( Equation 3 )\end{matrix}$$

$$\begin{matrix}[ Math . 4 ] & \\ {v}_{h} = \frac{Δ P}{m} + {I}_{b}^{- 1} ( {r}_{b} \times Δ P ) \times {r}_{b} & ( Equation 4 )\end{matrix}$$

$$\begin{matrix}[ Math . 5 ] & \\ ( {V}_{h} - {v}_{h} + {c}_{rep} {V}_{h}^{′} ) \cdot {F}_{X} = 0 & ( Equation 5 )\end{matrix}$$

$$\begin{matrix}[ Math . 6 ] & \\ ( {V}_{h} - {v}_{h} ) \cdot {F}_{y} = 0 & ( Equation 6 )\end{matrix}$$

$$\begin{matrix}[ Math . 7 ] & \\ ( {V}_{h} - {v}_{h} ) \cdot {F}_{z} = 0 & ( Equation 7 )\end{matrix}$$

$$\begin{matrix}[ Math . 8 ] & \\ {V}_{gc} = {V}_{gc}^{′} - \frac{ΔP}{M} & ( Equation 8 )\end{matrix}$$

$$\begin{matrix}[ Math . 9 ] & \\ Ω = {Ω}^{′} - {I}_{h}^{- 1} ( {r}_{h} \times Δ P ) & ( Equation 9 )\end{matrix}$$

V′ₕ: head-side velocity at a contact point immediately before the impact time k
Vₕ: head-side velocity at the contact point immediately after the impact time k
v′ₙ: golf ball-side velocity at the contact point immediately before the impact time k
vₕ: golf ball-side velocity at the contact point immediately after the impact time k
V′_{gc}: velocity of the center of gravity of the head immediately before the impact time k
V_{gc}: velocity of the center of gravity of the head immediately after the impact time k
Q′: angular velocity around the center of gravity of the head immediately before the impact time k
Ω: angular velocity around the center of gravity of the head immediately after the impact time k
Iₕ: inertia tensor of the head
v′_{gc}: velocity of the center of gravity of the golf ball immediately before the impact time k
v_{gc}: velocity of the center of gravity of the golf ball immediately after the impact time k
ω′: angular velocity around the center of gravity of the golf ball immediately before the impact time k
ω: angular velocity around the center of gravity of the golf ball immediately after the impact time k
I_{b}: moment of inertia of the golf ball
rh: vector from the center of gravity of the head to the contact point (see FIG. 8)
rb: vector from the center of gravity of the golf ball to the contact point (see FIG. 8)
M: mass of the head
m: mass of the golf ball
Cᵣₑₚ: coefficient of restitution
Fx: normal vector to the face of the head and with a unit length
Fy: horizontal tangent vector (η-axis direction) to the face of the head and with a unit length
Fz: vertical tangent vector (ζ-axis direction) to the face of the head and with a unit length

The arithmetic circuit 10 calculates V′ₕ, v′ₕ, V′_{gc}, Ω′, v′_{gc}, ω′, rh, rb, F_{X}, F_{Y}, and F_{Z} by using the parameters B1 to B8. Furthermore, the arithmetic circuit 10 calculates ΔP by performing the operation of the above-described Equations 2 to 9. ΔP is momentum transferred to the golf ball 210 by the golf club 200. Subsequently, the velocity of the center of gravity v_{gc} and the angular velocity ω are calculated by substituting ΔP in the following Equations 10 and 11. Incidentally, in the present disclosure, velocity is not a scalar quantity but a vector.

$$\begin{matrix}[ Math . 10 ] & \\ {v}_{gc} = \frac{Δ P}{m} & ( Equation 10 )\end{matrix}$$

$$\begin{matrix}[ Math . 11 ] & \\ ω = {I}_{b}^{- 1} ( {r}_{b} \times Δ P ) & ( Equation 11 )\end{matrix}$$

Next, the arithmetic circuit 10 calculates, in accordance with the velocity of the center of gravity v_{gc} and the angular velocity ω, a trajectory of the golf ball 210 in consideration of drag, lift, and hydrodynamic torque in the air (Step S6). The arithmetic circuit 10 calculates a trajectory of the golf ball 210 by using a method disclosed in the following document, for example. The arithmetic circuit 10 causes the display device 16 to display calculated results in Steps S4 to S6. After this, the sequential operation ends.

Takeshi NARUO, Taketo MIZOTA, “Aerodynamic force measurement of a golf ball and 3D trajectory analysis”, NAGARE, Journal of Japan Society of Fluid Mechanics, 23 (2004) 203-211.

The inventor of the present application performed an experiment to be described below to make an effect achieved by the arithmetic circuit 10 clearer. Specifically, the inventor of the present application hit the golf ball 210 with the golf club 200 more than once. Then, the inventor of the present application calculated, as a trajectory of the ball, a carry, a ball speed, a launch angle, a carry side, a maximum height, and a launch direction by using the arithmetic circuit 10. Additionally, the inventor of the present application calculated a carry, a ball speed, a launch angle, a carry side, a maximum height, and a launch direction by using a TrackMan. Furthermore, the inventor of the present application calculated a location in the η-axis direction of a point of impact of the golf ball 210 on the head of the golf club 200, and a location in the ζ-axis direction of a point of impact of the golf ball 210 on the head of the golf club 200 by using the arithmetic circuit 10. Furthermore, the inventor of the present application measured a location in the η-axis direction of a point of impact of the golf ball 210 on the head of the golf club 200, and a location in the ζ-axis direction of a point of impact of the golf ball 210 on the head of the golf club 200 by using pressure-sensitive paper (IMPACT MARKER manufactured by DAIYA GOLF Co., Ltd.) affixed to the face of the head of the golf club 200 in advance. The pressure-sensitive paper is discolored by impact of the golf ball 210. Subsequently, the inventor of the present application compared calculated results obtained by the arithmetic circuit 10 and calculated results obtained by the TrackMan and also compared calculated results obtained by the arithmetic circuit 10 with measured results.

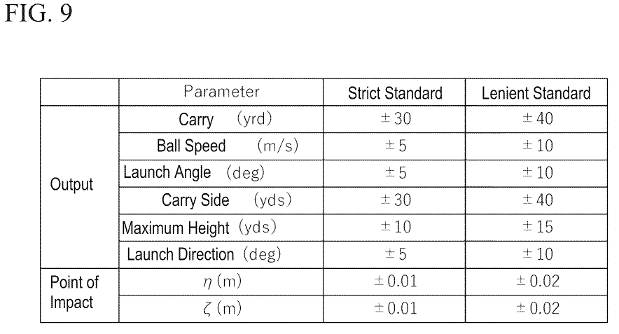

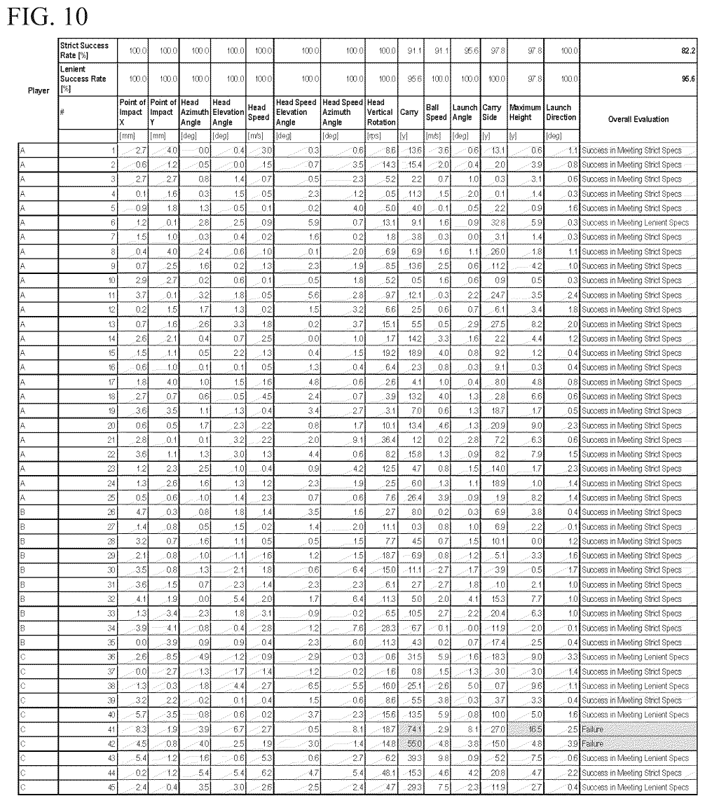

FIG. 9 is a table illustrating judgement criteria. In FIG. 9, as for six indicators of a carry, a ball speed, a launch angle, a carry side, a maximum height, and a launch direction, standards based on differences between the calculated results obtained by the arithmetic circuit 10 and the calculated results obtained by the TrackMan were used. Furthermore, as for two indicators of a location in the η-axis direction of a point of impact of the golf ball 210 on the head of the golf club 200 and a location in the ζ-axis direction of a point of impact of the golf ball 210 on the head of the golf club 200, standards based on differences between the calculated results obtained by the arithmetic circuit 10 and the measured results were used. FIG. 10 is a table illustrating experimental results. A single row corresponds to a single swing, and a difference value was entered for each indicator. Furthermore, when “Strict Standard” was met for all of eight indicators illustrated in FIG. 9, an overall evaluation in FIG. 10 was rated as “Success in Meeting Strict Specs”. In a case where “Strict Standard” was not met, when “Lenient Standard” was met for all of the eight indicators illustrated in FIG. 9, the overall evaluation in FIG. 10 was rated as “Success in Meeting Lenient Specs”. Furthermore, when “Strict Standard” and “Lenient Standard” were not met, the overall evaluation in FIG. 10 was rated as “Failure”. As illustrated in FIG. 10, it is found that good experimental results have been obtained. Hence, it can be considered that the calculated results obtained by the arithmetic circuit 10 has a degree of reliability close to that of the calculated results obtained by the TrackMan. Then, in the arithmetic circuit 10, when the sensor unit 100 is installed at the golf club 200 and a program performed by the arithmetic circuit 10 is installed on a personal computer or server, the parameters B1 to B8 indicating a state of the golf club 200 at a time of impact between the golf club 200 and the golf ball 210 can be calculated. Hence, in the arithmetic circuit 10, an expensive TrackMan is optional.

Furthermore, the TrackMan can calculate a velocity of the center of gravity v_{gc} of the golf ball 210 (object to be hit) and an angular velocity ω of the golf ball 210 (object to be hit). However, the TrackMan is unable to calculate parameters B1 to B8. On the other hand, the arithmetic circuit 10 can calculate a velocity of the center of gravity v_{gc}, an angular velocity ω, and parameters B1 to B8. Thus, the arithmetic circuit 10 can calculate parameters that the TrackMan is unable to calculate. The parameters B1 to B8 may be used in the teaching of golf, for example.

### (Modification)

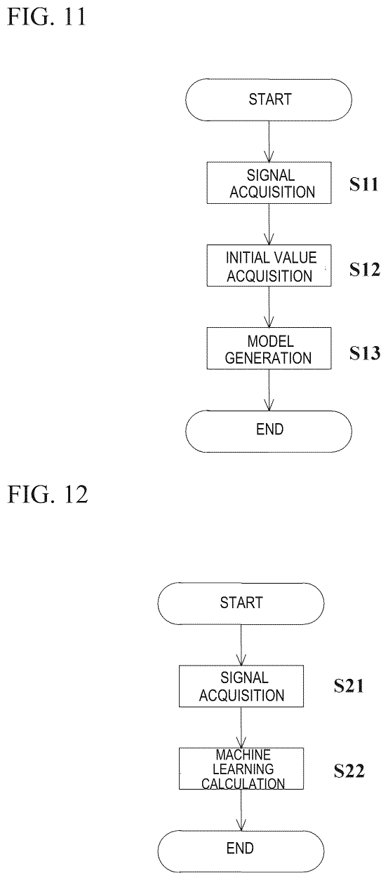

An arithmetic circuit 10a according to a modification will be described below with reference to drawings. FIGS. 11 and 12 are flowcharts illustrating a sequence of operations performed by the arithmetic circuit 10a. Note that FIG. 4 will be used as a block diagram of an arithmetic device 1a.

The arithmetic circuit 10a generates a machine learning model and also calculates, by using the machine learning model, a velocity of the center of gravity v_{gc} of the golf ball 210 and an angular velocity ω of the golf ball 210 produced by impact between the golf club 200 and the golf ball 210.

First, the generation of a machine learning model will be described. The arithmetic circuit 10a acquires an X-axis bending signal Sig1, a Y-axis bending signal Sig2, and a twisting signal Sig3 (Step S11, signal acquisition step). Step S11 is the same as Step S1, and a description thereof is therefore omitted.

Next, the arithmetic circuit 10a acquires a velocity of the center of gravity v_{gc} of the golf ball 210 (hitting object) and an angular velocity ω of the golf ball 210 (object to be hit) produced by impact between the golf club 200 (object to be measured) and the golf ball 210 (object to be hit) (Step S12, initial value acquisition step). As an acquisition method, the TrackMan is caused to calculate a velocity of the center of gravity v_{gc} of the golf ball 210 and an angular velocity ω of the golf ball 210 when the user hits the golf ball 210 with the golf club 200.

The arithmetic circuit 10a generates a machine learning model (Step S13, model generation step) by using, as training data, the X-axis bending signal Sig1, the Y-axis bending signal Sig2, and the twisting signal Sig3 acquired in Step S11 (signal acquisition step), and the velocity of the center of gravity v_{gc} of the golf ball 210 and the angular velocity ω of the golf ball 210 acquired in Step S12 (initial value acquisition step). As described below, the machine learning model outputs, in accordance with the X-axis bending signal Sig1, the Y-axis bending signal Sig2, and the twisting signal Sig3, a velocity of the center of gravity v_{gc} of the golf ball 210 and an angular velocity ω of the golf ball 210. When Step S13 is repeated, the machine learning model is modified. This improves the accuracy of output results of the machine learning model. The machine learning model is generated by the above-described steps.

Next, the calculation of a velocity of the center of gravity v_{gc} and an angular velocity ω performed by the machine learning model will be described. The arithmetic circuit 10a acquires an X-axis bending signal Sig1, a Y-axis bending signal Sig2, and a twisting signal Sig3 (Step S21, signal acquisition step). Step S21 is the same as Step S1, and a description thereof is therefore omitted.

Next, the arithmetic circuit 10a calculates, by using the machine learning model, in accordance with the X-axis bending signal Sig1, the Y-axis bending signal Sig2, and the twisting signal Sig3 acquired in Step S21 (signal acquisition step), a velocity of the center of gravity v_{gc} of the golf ball 210 and an angular velocity ω of the golf ball 210 produced by impact between the golf club 200 (object to be measured) and the golf ball 210 (object to be hit) (Step S22, machine learning calculation step). The arithmetic circuit 10a causes the display device 16 to display calculated results in Step S22. After this, the sequential operation ends.

### Other Embodiments

An arithmetic circuit according to the present disclosure is not limited to the arithmetic circuits 10 and 10a, and variations can be made within the scope of the gist of the disclosure.

Note that an object to be measured is not limited to the golf club 200. The golf club 200 may be, for example, a game controller. Furthermore, an object to be hit is not limited to the golf ball 210.

Note that the sensors 12a to 12c may detect a derivative value of the amount of deformation of the golf club 200. In this case, each of an X-axis bending amount aₓ(i), a Y-axis bending amount a_{y}(i), and a twisting amount aₜ(i) is a derivative value of the amount of deformation. Then, in Step S3, the arithmetic circuit 10 calculates, as an X-axis bending value Aₓ(i), a Y-axis bending value A_{y}(i), and a twisting value Aₜ(i), values obtained by integrating the X-axis bending amount aₓ(i), the Y-axis bending amount a_{y}(i), and the twisting amount aₜ(i) with respect to time.

Note that, in the signal value acquisition step, X-axis bending values, Y-axis bending values, and twisting values at respective one or more first times before the impact time k identified in the time identification step and at respective one or more second times after the impact time only have to be acquired.

Note that, in the first calculation step, one or more parameters indicating a state of the object to be measured at the impact time only have to be calculated by multiplying a plurality of X-axis bending values, a plurality of Y-axis bending values, and a plurality of twisting values acquired in the signal value acquisition step by a matrix.

Note that one or more parameters only have to include at least one of a location of a point of impact of the golf ball on the head of the golf club, a horizontal azimuth angle of the head, a head elevation angle, a head speed, a head speed elevation angle, a head speed azimuth angle, and a head vertical rotation speed.

Note that, in common with the arithmetic circuit 10, the arithmetic circuit 10a may also calculate a trajectory of the golf ball 210.

### REFERENCE SIGNS LIST

1, 1a arithmetic device
10, 10a arithmetic circuit
12 communication device
12a to 12c sensor
14 storage device
16 display device
100 sensor unit
200 golf club
210 golf ball

1. An arithmetic circuit configured to:
acquire an X-axis bending signal related to an amount of bending in an X-axis direction of a stick-like object that extends in a Z-axis direction, a Y-axis bending signal related to an amount of bending in a Y-axis direction of the stick-like object, and a twisting signal related to an amount of twisting around a Z axis of the stick-like object;
identify an impact time when the stick-like object hits another object, in accordance with the X-axis bending signal, the Y-axis bending signal, and the twisting signal;
acquire X-axis bending values, Y-axis bending values, and twisting values at one or more respective first times before the identified impact time and at one or more respective second times after the identified impact time, each X-axis bending value being a value related to a value indicated by the X-axis bending signal, each Y-axis bending value being a value related to a value indicated by the Y-axis bending signal, and each twisting value being a value related to a value indicated by the twisting signal; and
determine one or more parameters indicating a state of the stick-like object at the identified impact time by multiplying a plurality of the X-axis bending values, a plurality of the Y-axis bending values, and a plurality of the twisting values by a matrix.

2. The arithmetic circuit according to claim 1,
wherein the stick-like object a golf club, and
wherein the other object is a golf ball.

3. The arithmetic circuit according to claim 2, wherein the one or more parameters include at least one of:
a location of a point of impact of the golf ball on a head of the golf club,
a horizontal azimuth angle of the head,
a head elevation angle,
a head speed,
a head speed elevation angle,
a head speed azimuth angle, or
a head vertical rotation speed.

4. The arithmetic circuit according to claim 3, wherein the arithmetic circuit is configured to determine, in accordance with the one or more parameters, a velocity of a center of gravity of the golf ball and an angular velocity of the golf ball produced by impact between the golf club and the golf ball.

5. An arithmetic method, comprising:
acquiring an X-axis bending signal related to an amount of bending in an X-axis direction of a stick-like object that extends in a Z-axis direction, a Y-axis bending signal related to an amount of bending in a Y-axis direction of the stick-like object, and a twisting signal related to an amount of twisting around a Z axis of the stick-like object;
identifying an impact time when the stick-like object hits another object, in accordance with the X-axis bending signal, the Y-axis bending signal, and the twisting signal;
acquiring X-axis bending values, Y-axis bending values, and twisting values at one or more respective first times before the identified impact time and at one or more respective second times after the identified impact time, each X-axis bending value being a value related to a value indicated by the X-axis bending signal, each Y-axis bending value being a value related to a value indicated by the Y-axis bending signal, and each twisting value being a value related to a value indicated by the twisting signal; and
determining one or more parameters indicating a state of the stick-like object at the identified impact time by multiplying a plurality of the X-axis bending values, a plurality of the Y-axis bending values, and a plurality of the twisting values by a matrix.

6. An arithmetic circuit configured to:
acquire an X-axis bending signal related to an amount of bending in an X-axis direction of a stick-like object that extends in a Z-axis direction, a Y-axis bending signal related to an amount of bending in a Y-axis direction of the stick-like object, and a twisting signal related to an amount of twisting around a Z axis of the stick-like object;
acquire a velocity of a center of gravity of another object and an angular velocity of the other object produced by impact between the stick-like object and the other object; and
generate a machine learning model by using, as training data, the X-axis bending signal, the Y-axis bending signal, and the twisting signal, and the velocity of the center of gravity of the other object and the angular velocity of the other object,
wherein the machine learning model is trained to output, in accordance with the X-axis bending signal, the Y-axis bending signal, and the twisting signal, the velocity of the center of gravity of the other object and the angular velocity of the other object.
